(19) United States
(12) Patent Application Publication
(10) Pub. No.: US 2025/0098106 A1
(43) Pub. Date: Mar. 20, 2025

(54) CONNECTING MECHANISM OF COMBINATION COMPUTER CASE AND FAN STRUCTURE

(71) Applicant: Shanghai TRYX Technology Co., Ltd., Shanghai City (CN)

(72) Inventor: Zheng-Gang Su, Shanghai City (CN)

(21) Appl. No.: 18/532,654

(22) Filed: Dec. 7, 2023

(30) Foreign Application Priority Data
Sep. 18, 2023 (CN) 2023225337790

(51) Int. Cl. H05K 7/20; G06F 1/20

(52) U.S. Cl. CPC H05K 7/20172; G06F 1/20

(57) ABSTRACT

A connecting mechanism includes at least two fan housings juxtaposed to each other. Each of the at least two fan housings has an outside provided with two magnetically attractive elements arranged symmetrically. The two magnetically attractive elements have the same structure. The two magnetically attractive elements are secured to and distributed horizontally on each of the at least two fan housings. A first one of the two magnetically attractive elements of one of the at least two fan housings is magnetically attracted by and connected with a second one of the two magnetically attractive elements of an adjacent one of the at least two fan housings.

### BACKGROUND OF THE INVENTION

### Field of the Invention

The present invention relates to a connecting mechanism and, more particularly, to a connecting mechanism of a combination computer case and fan structure.

### Description of the Related Art

A computer fan or cooling fan is available for a radiator or a case of the computer to provide a heat dissipation effect. In general, the size of a computer fan has a diameter from 2.5 cm to 30 cm and a thickness from 6 mm to 76 mm. According to different operating requirements, the computer fan is adapted to an AC (alternating current) power supply or a DC (direct current) power supply. Multiple computer fans are arranged and connected serially to enhance the heat dissipation effect.

A conventional combined structure of a mini computer circuit board and a heat dissipation device was disclosed in the Chinese Patent Publication No. CN218446534U, and comprises a circuit board, a central processor, a memory component, an SSD component, a multimedia component, a graphics card, a graphics card socket, a start button, a power interface, pins, and multiple peripheral interfaces. The central processor is mounted on a first side of the circuit board. A protective frame is secured on a second heat dissipation fin. A reinforcing frame is secured to a second side of the circuit board by screws which extend through the circuit board and securely connect the protective frame. Two first connecting pieces are secured to two sides of a first heat dissipation fin. Two second connecting pieces are secured to two sides of the second heat dissipation fin. The first connecting pieces and the second connecting pieces are secured to fans by screws. A third connecting piece is secured to the fan by screws. The first side of the circuit board is provided with a support block. The support block is connected with a stop bar through a connecting column. The connecting column is locked in four corner holes of a placement frame. The placement frame is secured to the circuit board by screws.

The above-mentioned multiple fans are connected and fixed with the brackets or frames through screws. However, the fans are not connected and arranged smoothly during the assembly process so that some of the fans easily protrude outward and some of the fans easily retract inward, thereby decreasing the aesthetic quality of the whole fans. In addition, the fans are distributed individually during assembly so that the fans cannot be positioned during installation. Thus, the fans are not easily aligned with each other.

### BRIEF SUMMARY OF THE INVENTION

In accordance with the present invention, there is provided a connecting mechanism comprising at least two fan housings juxtaposed to each other. Each of the at least two fan housings has an outside provided with two magnetically attractive elements arranged symmetrically. The two magnetically attractive elements have the same structure. The two magnetically attractive elements are secured to and distributed horizontally on each of the at least two fan housings. A first one of the two magnetically attractive elements of one of the at least two fan housings is magnetically attracted by and connected with a second one of the two magnetically attractive elements of an adjacent one of the at least two fan housings.

According to the primary advantages of the present invention, each of the at least two fan housings is provided with two magnetically attractive elements which are arranged symmetrically at two opposite sides of each of the at least two fan housings, so that two adjacent fan housings are secured previously. Thus, the two magnetically attractive elements provide a magnetically attracting effect so that multiple fan housings are assembled easily and arranged smoothly. In addition, multiple fan housings are integrated to enhance the aesthetic quality of the fan housings.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a perspective view of a connecting mechanism in accordance with the preferred embodiment of the present invention.

FIG. 2 is a locally enlarged view of the connecting mechanism taken along circle A as shown in FIG. 1.

FIG. 3 is another perspective view of the connecting mechanism in accordance with the preferred embodiment of the present invention.

FIG. 4 is a partial exploded perspective view of the connecting mechanism as shown in FIG. 1.

FIG. 5 is a partial exploded perspective view of the connecting mechanism as shown in FIG. 3.

### DETAILED DESCRIPTION OF THE INVENTION

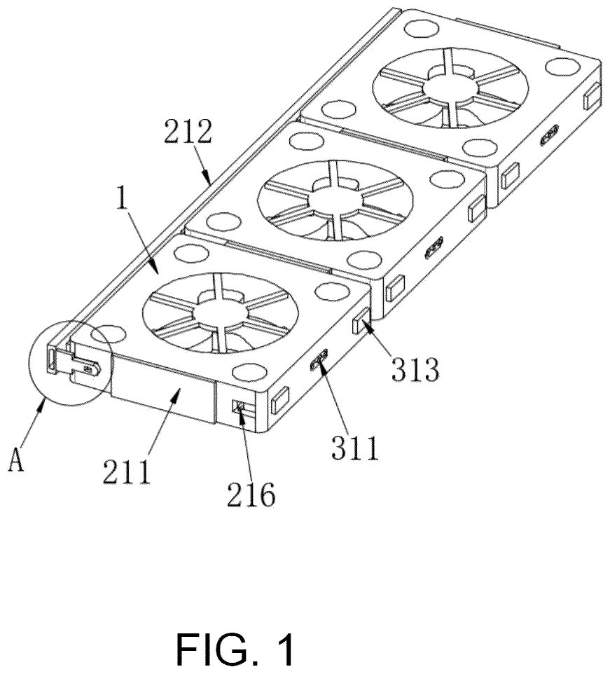

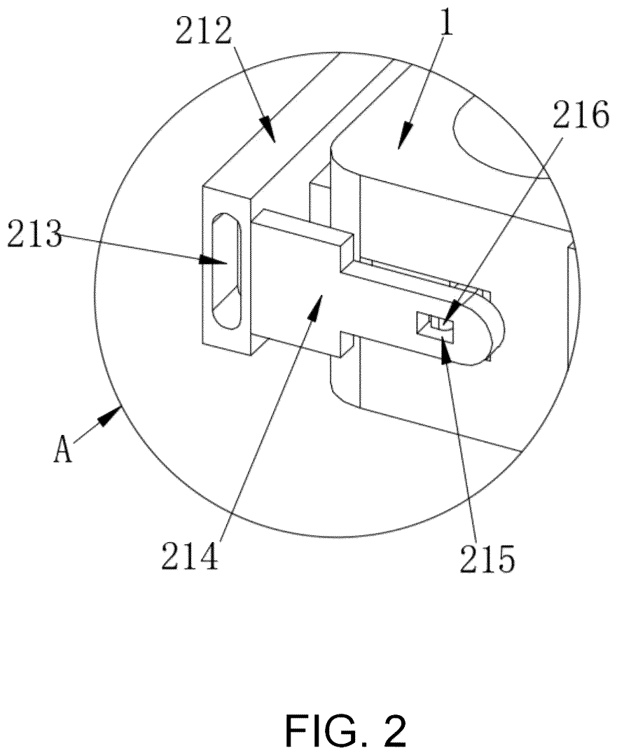

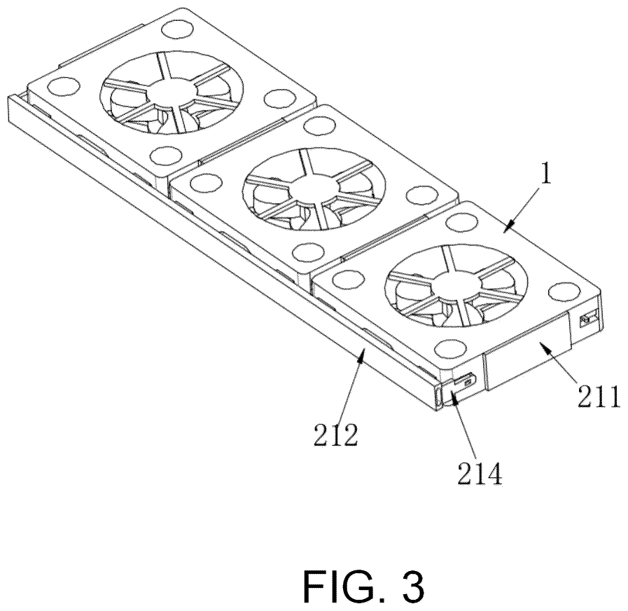

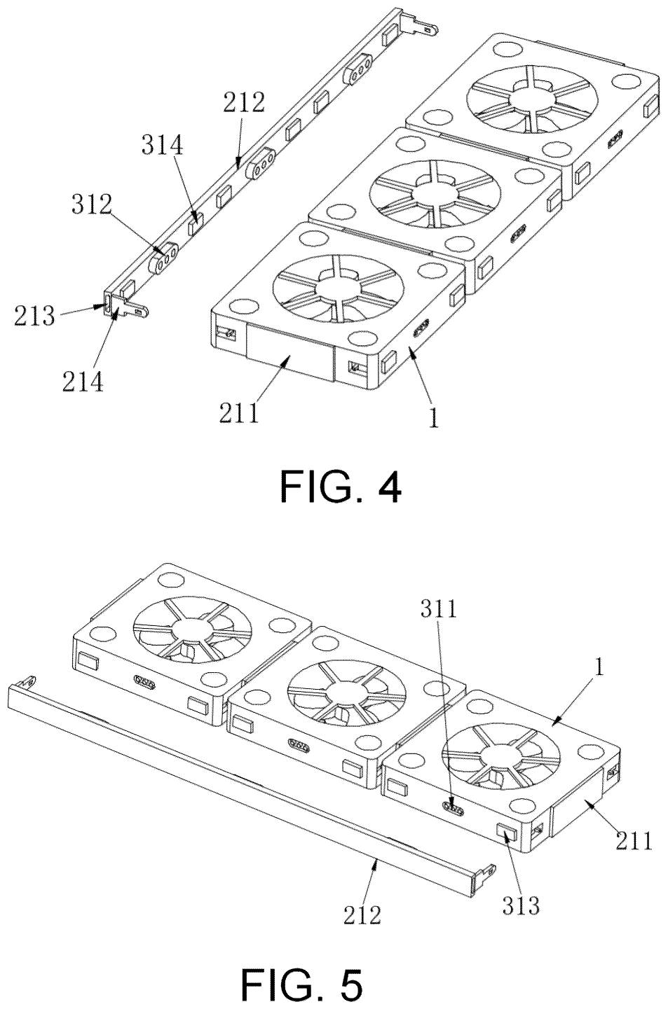

Referring to FIGS. 1-5, a connecting mechanism of a combination computer case and fan structure in accordance with the preferred embodiment of the present invention comprises at least two fan housings 1 juxtaposed to each other.

Each of the at least two fan housings 1 has an outside provided with two magnetically attractive elements 211 arranged symmetrically. The two magnetically attractive elements 211 have the same structure. The two magnetically attractive elements 211 are secured to and distributed horizontally on each of the at least two fan housings 1. A first one of the two magnetically attractive elements 211 of one of the at least two fan housings 1 is magnetically attracted by and connected with a second one of the two magnetically attractive elements 211 of an adjacent one of the at least two fan housings 1.

In such a manner, the at least two fan housings 1 are fixed previously so that multiple fan housings 1 are arranged serially without causing disorder. In addition, multiple fan housings 1 are integrated to facilitate installation of the multiple fan housings 1.

In the preferred embodiment of the present invention, the first one of the two magnetically attractive elements 211 of one of the at least two fan housings 1 is a magnet S (or south) pole, and the second one of the two magnetically attractive elements 211 of the adjacent one of the at least two fan housings 1 is a magnet N (or north) pole.

In such a manner, the at least two fan housings 1 are magnetically connected by the magnet S pole and the magnet N pole so that multiple fan housings 1 are fixed by magnetically attractive connection.

In the preferred embodiment of the present invention, the connecting mechanism further comprises at least one light emitting lamp strip 212 mounted on the at least two fan housings 1. The at least one light emitting lamp strip 212 is provided with at least two locking modules locked on the at least two fan housings 1. The at least two locking modules connect two ends of the at least one light emitting lamp strip 212 with the at least two fan housings 1.

In the preferred embodiment of the present invention, each of the at least two locking modules includes a mounting plate 214, a locking groove 215, and a locking block 216. The mounting plate 214 is secured on the at least one light emitting lamp strip 212 and close to one of the at least two fan housings 1. The locking block 216 is secured on each of the at least two fan housings 1. The locking groove 215 is formed in the mounting plate 214 and mates with the locking block 216.

Preferably, the locking block 216 is made of plastic material with determined toughness and elasticity. In such a manner, when the mounting plate 214 is moved toward one of the at least two fan housings 1, the locking block 216 is compressed. After the locking groove 215 aligns with the locking block 216, the locking block 216 is inserted into and locked in the locking groove 215 to restrict the mounting plate 214.

In the preferred embodiment of the present invention, any one of the two ends of the at least one light emitting lamp strip 212 is provided with a TYPE-C connecting port 213 for providing a power supply input.

In such a manner, a light emitting action is processed in the case of the computer through the TYPE-C connecting port 213 to enhance the aesthetic quality of the case.

In the preferred embodiment of the present invention, each of the at least two fan housings 1 is provided with at least one first magnetically attractive member 313 close to the at least one light emitting lamp strip 212. The at least one first magnetically attractive member 313 is secured on each of the at least two fan housings 1. The at least one light emitting lamp strip 212 is provided with multiple second magnetically attractive member 314 matching the at least one first magnetically attractive member 313 of each of the at least two fan housings 1. The second magnetically attractive member 314 are secured on the at least one light emitting lamp strip 212.

Preferably, the at least one first magnetically attractive member 313 is a magnet, and each of the second magnetically attractive member 314 is a magnet. In such a manner, the at least one first magnetically attractive member 313 and the second magnetically attractive member 314 are attracted mutually so that the at least one light emitting lamp strip 212 is attached to the at least two fan housings 1 previously, to prevent the operator from constantly holding the at least one light emitting lamp strip 212 during a long period of time.

In the preferred embodiment of the present invention, each of the at least two fan housings 1 is provided with at least one telecommunication port 311, and the at least one light emitting lamp strip 212 is provided with multiple telecommunication connectors 312 corresponding to the at least one telecommunication port 311 of each of the at least two fan housings 1.

In such a manner, when the at least one light emitting lamp strip 212 is installed on the at least two fan housings 1, each of the telecommunication connectors 312 is connected to the at least one telecommunication port 311. At the same time, the at least one light emitting lamp strip 212 provides a dustproof function to protect and prevent the at least one telecommunication port 311 from being contaminated by dust or dirt.

In another preferred embodiment of the present invention, the first one of the two magnetically attractive elements 211 of one of the at least two fan housings 1 is a magnet S (or south) pole or a magnet N (or north) pole, and the second one of the two magnetically attractive elements 211 of the adjacent one of the at least two fan housings 1 is a magnetic patch. Preferably, the magnetic patch is made of iron, nickel or cobalt to provide a magnetically attractive effect. Thus, the connecting mechanism provides different magnetically attractive means to satisfy the requirement of different equipment.

In practice, when the at least two fan housings 1 are installed, the first one of the two magnetically attractive elements 211 of one of the at least two fan housings 1 is magnetically attracted by and connected with the second one of the two magnetically attractive elements 211 of an adjacent one of the at least two fan housings 1, so that the at least two fan housings 1 are connected magnetically. Thus, multiple fan housings 1 are connected serially. When the at least one light emitting lamp strip 212 is mounted on the at least two fan housings 1, the at least one first magnetically attractive member 313 and the second magnetically attractive member 314 are attracted mutually so that the at least one light emitting lamp strip 212 is attached to the at least two fan housings 1. At the same time, when the mounting plate 214 is moved toward one of the at least two fan housings 1, the locking block 216 is compressed. After the locking groove 215 aligns with the locking block 216, the locking block 216 is inserted into and locked in the locking groove 215 to lock the mounting plate 214. At the same time, when the at least one light emitting lamp strip 212 is installed on the at least two fan housings 1, each of the telecommunication connectors 312 is connected to the at least one telecommunication port 311.

Accordingly, the connecting mechanism of the present invention has the following advantages.

1. Each of the at least two fan housings 1 is provided with two magnetically attractive elements 211 which are arranged symmetrically at two opposite sides of each of the at least two fan housings 1, so that two adjacent fan housings 1 are secured previously. Thus, the two magnetically attractive elements 211 provide a magnetically attracting effect so that multiple fan housings 1 are assembled easily and arranged smoothly. In addition, multiple fan housings 1 are integrated to enhance the aesthetic quality of the fan housings 1.

2. The at least one light emitting lamp strip 212 is provided with at least two locking modules locked on the at least two fan housings 1. The locking block 216 is made of metal or plastic material with determined toughness and elasticity. In such a manner, when the mounting plate 214 is moved to contact the locking block 216, the locking block 216 is compressed. After the locking groove 215 aligns with the locking block 216, the locking block 216 is restored elastically and inserted into the locking groove 215 to lock the mounting plate 214 so that the at least one light emitting lamp strip 212 is restricted. Thus, the at least one light emitting lamp strip 212 enhances the aesthetic quality of the fan housings 1. At the same time, the at least one light emitting lamp strip 212 provides a dustproof function to protect and prevent the at least one telecommunication port 311 from being contaminated by dust or dirt.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the scope of the invention.

1. A connecting mechanism, comprising:
at least two fan housings juxtaposed to each other;
wherein:
each of the at least two fan housings has an outside provided with two magnetically attractive elements arranged symmetrically;
the two magnetically attractive elements have the same structure;
the two magnetically attractive elements are secured to and distributed horizontally on each of the at least two fan housings; and
a first one of the two magnetically attractive elements of one of the at least two fan housings is magnetically attracted by and connected with a second one of the two magnetically attractive elements of an adjacent one of the at least two fan housings.

2. The connecting mechanism as claimed in claim 1, wherein the first one of the two magnetically attractive elements of one of the at least two fan housings is a magnet S pole, and the second one of the two magnetically attractive elements of the adjacent one of the at least two fan housings is a magnet N pole.

3. The connecting mechanism as claimed in claim 1, wherein the first one of the two magnetically attractive elements of one of the at least two fan housings is a magnet S pole or a magnet N pole, and the second one of the two magnetically attractive elements of the adjacent one of the at least two fan housings is a magnetic patch.

4. The connecting mechanism as claimed in claim 1, wherein:
the connecting mechanism further comprises at least one light emitting lamp strip mounted on the at least two fan housings;
the at least one light emitting lamp strip is provided with at least two locking modules locked on the at least two fan housings; and
the at least two locking modules connect two ends of the at least one light emitting lamp strip with the at least two fan housings.

5. The connecting mechanism as claimed in claim 4, wherein:
each of the at least two locking modules includes a mounting plate, a locking groove, and a locking block;
the mounting plate is secured on the at least one light emitting lamp strip and close to one of the at least two fan housings;
the locking block is secured on each of the at least two fan housings; and
the locking groove is formed in the mounting plate and mates with the locking block.

6. The connecting mechanism as claimed in claim 4, wherein any one of the two ends of the at least one light emitting lamp strip is provided with a TYPE-C connecting port for providing a power supply input.

7. The connecting mechanism as claimed in claim 4, wherein:
each of the at least two fan housings is provided with at least one first magnetically attractive member close to the at least one light emitting lamp strip;
the at least one first magnetically attractive member is secured on each of the at least two fan housings;
the at least one light emitting lamp strip is provided with multiple second magnetically attractive member matching the at least one first magnetically attractive member of each of the at least two fan housings; and
the second magnetically attractive member are secured on the at least one light emitting lamp strip.

8. The connecting mechanism as claimed in claim 4, wherein each of the at least two fan housings is provided with at least one telecommunication port, and the at least one light emitting lamp strip is provided with multiple telecommunication connectors corresponding to the at least one telecommunication port of each of the at least two fan housings.
